(19) United States
(12) Patent Application Publication
(10) Pub. No.: US 2016/0268882 A1
(43) Pub. Date: Sep. 15, 2016

(54) LINEAR MOTOR

(71) Applicant: SUMITOMO HEAVY INDUSTRIES, LTD., Tokyo (JP)

(72) Inventors: Kotaro WADA, Yokosuka-shi (JP); Dotaro USUI, Yokosuka-shi (JP); Takashi IKEDA, Yokosuka-shi (JP); Hirokazu YUSA, Yokosuka-shi (JP)

(21) Appl. No.: 15/062,361

(22) Filed: Mar. 7, 2016

(30) Foreign Application Priority Data
Mar. 9, 2015 (JP) 2015-045543
Mar. 3, 2016 (JP) 2016-040727

(51) Int. Cl. H02K 41/02; H02K 1/17; H01J 37/20; H02K 1/02

(52) U.S. Cl. CPC H02K 41/02; H02K 1/02; H02K 1/17; H01J 37/20

(57) ABSTRACT

A linear-motor stator is configured by connecting a plurality of magnetic circuits along the axis of travel of the forcer (along the x-axis). The magnetic circuits are furnished with yokes and pluralities of field magnets fixed to the yokes. High-magnetic permeability members of magnetic permeability higher than that of the yokes are provided where adjoining magnetic circuits are connected, straddling the connections.

### BACKGROUND

1. Technical Field

Certain embodiments of the invention relate to linear motors.

2. Description of Related Art

Linear motors are used to convert electrical energy into linear motion. FIG. 1 is a perspective view of a conventional linear motor. As illustrated in FIG. 1, the linear motor 2r is furnished with a forcer 10 and a stator 20r. The stator 20r comprises a yoke 22 including a pair of yoke backs 22a and 22b disposed in opposition, between which the forcer 10 is sandwiched, and a plurality of field magnets 24 provided on inner-side lateral faces S1a and S1b of the yoke backs 22a and 22b, paralleling the axis along which the forcer 10 can move (x-axis direction). The plurality of field magnets 24 are glued on according to a predetermined magnetic-pole pitch, and such that the N poles and S poles appear in alternation. The yoke 22 and the field magnets 24 form a magnetic circuit.

FIGS. 2A and 2B are perspective views illustrating the stator 20r. In a linear motor 2r in which the moving range of the forcer is large, it is necessary to make the yoke 22 long, but constituting a longer yoke 22 in such instances is problematic, owing to cost as well as difficulties with machining precision, and consequently longer yokes 22 are often constructed by manufacturing several shorter yokes 23 as indicated in FIG. 2A, and connecting them together as indicated in FIG. 2B.

FIGS. 3A and 3B are plan views of the yoke 22. As indicated in FIG. 3A, when shorter yokes 23 are connected to construct a longer yoke 22, gaps (air strata) 26 originating in discrepancies in manufacturing the yokes 23 arise in the connecting area 25 between them. These gaps 26 turn out to be areas of high magnetic resistance (accordingly, of low magnetic permeability).

The magnetic flux Φ that a field magnet 24 generates passes through the yoke 22 and flows into a neighboring field magnet 24. However, in a case in which the yoke 22 is not an integrated component but has an articulated structure, magnetic flux Φ cannot negotiate the high-magnetic-resistance sections of the connecting area 25, such that a portion Φ_{EXT} of the magnetic flux leaks to the exterior of the yoke 22. Alternatively, if the surface of the yokes 23 is plated as indicated in FIG. 3B, the plating 27 turns out to be a section of high magnetic resistance, becoming the cause of magnetic field leakage.

A technique for reducing magnetic field leakage by especially devising the form of the connecting area between the yokes is disclosed in Japanese Unexamined Utility Model App. Pub. No. H05-8793.

Although the leakage flux density of conventional linear motors, being on the order of several tens of mT, does not lead to problems in the majority of applications, in devices employing electron beams, and in like applications in which magnetic fields have an impact on the target object, reducing magnetic field leakage to still lower levels has been desired.

### SUMMARY

The invention provides a linear motor that reduces a stray magnetic field.

According to an aspect of the invention, there is provided a linear motor. The linear motor includes a movable element and a stator that includes a plurality of magnetic circuits connected in a movable direction of the movable element. Each of the magnetic circuits includes a yoke and a plurality of field magnets fixed to the yoke. A high-magnetic permeability member of which magnetic permeability is higher than magnetic permeability of the yoke is provided at a connecting portion between adjacent magnetic circuits so as to extend across the connecting portion.

According to this aspect, since the high-magnetic permeability member is provided at the connecting portion, a path having low magnetic resistance is formed so as to bypass portions that have high magnetic resistance and are formed at the connecting portion. Accordingly, it is possible to reduce magnetic flux that leaks out of the yoke.

Both ends of the high-magnetic permeability member may overlap at least a part of the field magnets of the magnetic circuit.

Accordingly, since it is possible to guide the magnetic flux, which is generated by the field magnets, to the inside of the high-magnetic permeability member, it is possible to reduce a stray magnetic field.

The high-magnetic permeability member may be embedded in the yoke.

Accordingly, it is possible to increase a contact area between the high-magnetic permeability member and the yoke. Therefore, it is possible to guide more magnetic flux to the inside of the high-magnetic permeability member.

The high-magnetic permeability member may be provided on a surface of the yoke. In this case, the assembling of the magnetic circuits becomes easy.

The yoke may include a pair of back yokes that are provided so as to face each other with the movable element interposed therebetween in a direction perpendicular to the movable direction. The plurality of field magnets may be provided on inner surfaces of the back yokes. A recess to which the high-magnetic permeability member is fitted may be formed in an end face of the back yoke.

The yoke may include a pair of back yokes that are provided so as to face each other with the movable element interposed therebetween in a direction perpendicular to the movable direction. The plurality of field magnets may be provided on inner surfaces of the back yokes. The high-magnetic permeability member may be provided on an outer surface of adjacent back yoke.

In this case, the assembling of the magnetic circuits becomes easy.

A groove may be provided on an outer surface of the back yoke and the high-magnetic permeability member may be embedded in the groove.

Accordingly, since it is possible to improve assembling accuracy during the assembling of the high-magnetic permeability member with the back yoke, and the back yoke and the high-magnetic permeability member can be positioned so as to be flush with each other. Therefore, it is possible to reduce a stray magnetic field.

The high-magnetic permeability member may have the shape of a plate. The high-magnetic permeability member may have the shape of a rod.

According to another aspect of the invention, there is provided a stage device. The stage device may include any one of the above-mentioned linear motors.

It is to be noted that any arbitrary combination or rearrangement of the above-described structural components and so forth is effective as and encompassed by the present embodiments.

Moreover, this summary of the invention does not necessarily describe all necessary features so that the invention may also be a sub-combination of these described features.

### BRIEF DESCRIPTION OF THE DRAWINGS

Embodiments will now be described, by way of example only, with reference to the accompanying drawings which are meant to be exemplary, not limiting, and wherein like elements are numbered alike in several Figures, in which:

FIG. 1 is a perspective view of a linear motor in the related art.

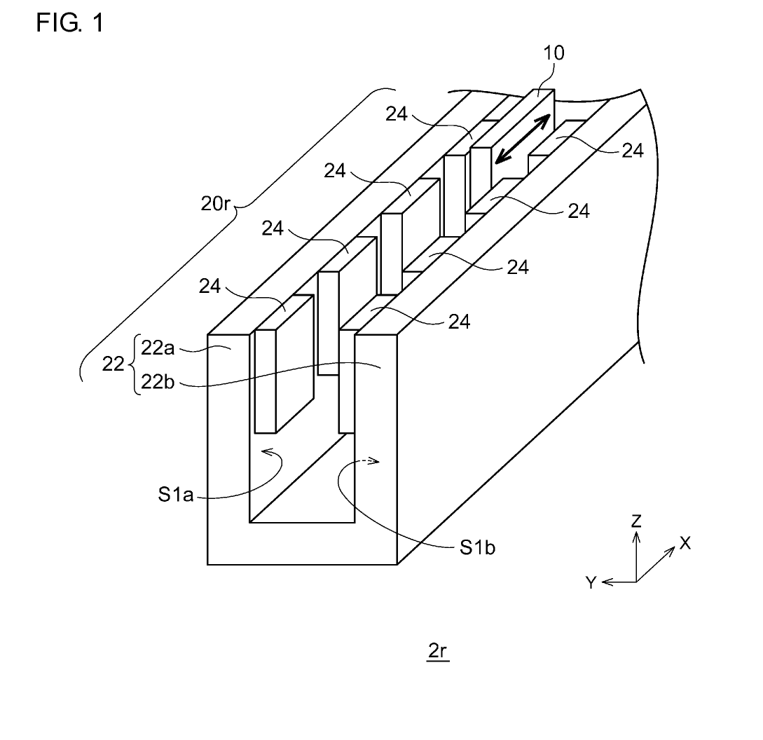

FIGS. 2A and 2B are perspective views of a stator.

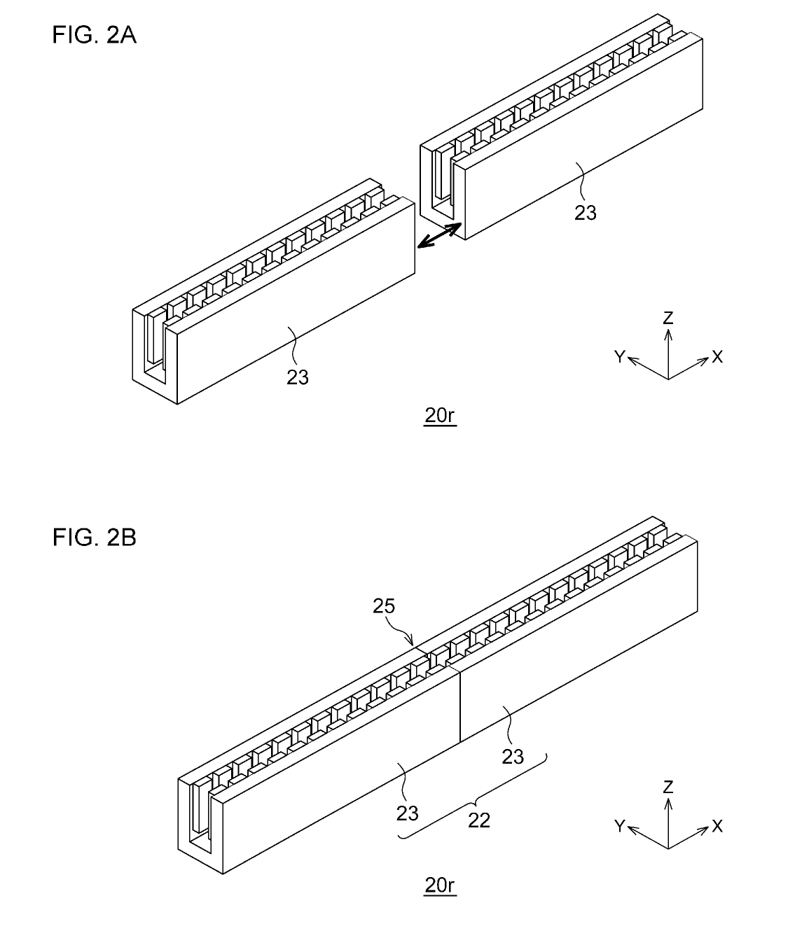

FIGS. 3A and 3B are plan views of a yoke.

FIGS. 4A and 4B are views showing a stator of a linear motor according to an embodiment.

FIG. 5 is an assembly diagram of the stator.

FIG. 6 is a plan view of the stator.

FIGS. 7A and 7B are perspective views of a stator according to a first modification.

FIG. 8 is a perspective view of a stator according to a second modification.

FIGS. 9A and 9B are views of a stator of a linear motor according to another embodiment.

FIGS. 10A and 10B are perspective views of stators according to third and fourth modifications.

FIG. 11 is a perspective view of a stator according to a fifth modification.

FIGS. 12A and 12B are cross-sectional views of a stator according to a sixth modification.

FIG. 13 is a plan view of a stage device using the linear motor according to the embodiment.

### DETAILED DESCRIPTION

The invention will now be described based on preferred embodiments which do not intend to limit the scope of the present invention but exemplify the invention. All of the features and the combinations thereof described in the embodiment are not necessarily essential to the invention.

### First Embodiment

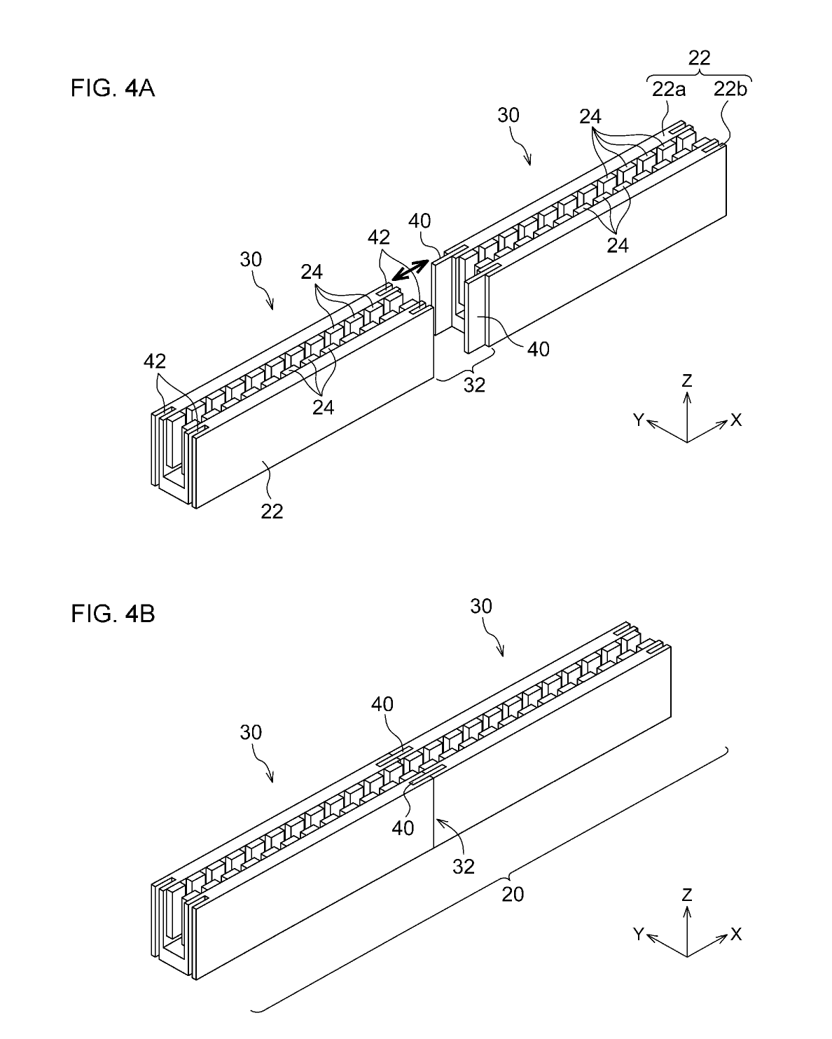

FIGS. 4A and 4B are views showing a stator 20 of a linear motor according to a first embodiment. The stator 20 includes a plurality of magnetic circuits 30 that are connected in a movable direction of a movable element (the x-axis direction). Each of the magnetic circuits 30 includes a yoke 22 and a plurality of field magnets 24 fixed to the yoke 22. High-magnetic permeability members 40 of which the magnetic permeability is higher than the magnetic permeability of the yoke 22 are provided at a connecting portion 32 between adjacent magnetic circuits 30 so as to extend across the connecting portion 32.

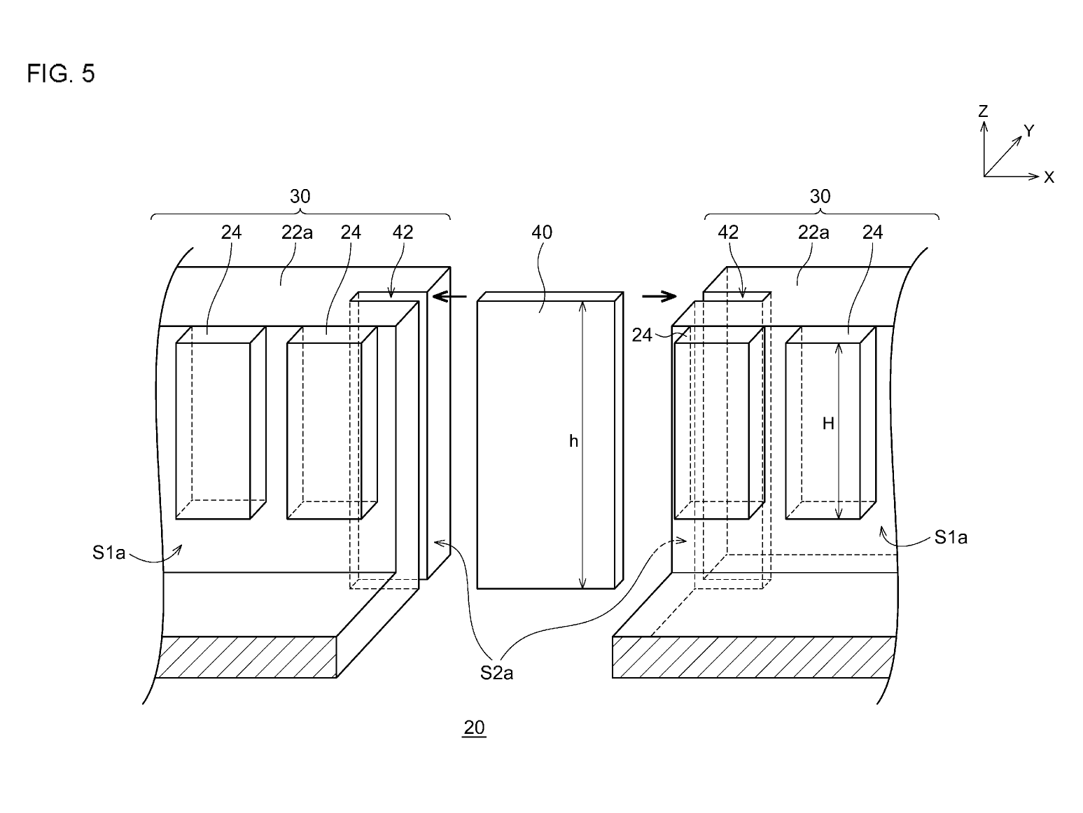

In this embodiment, the plate-like high-magnetic permeability members 40 are embedded in the yoke 22. FIG. 5 is an assembly diagram of the stator 20. In FIG. 5, only one back yoke 22a of a pair of back yokes 22a and 22b, which are provided so as to face each other with the movable element interposed therebetween in a direction (Y direction) perpendicular to the movable direction (the x-axis direction), is shown and the other back yoke 22b is omitted. The field magnets 24 are provided on an inner surface S1a of the back yoke 22a. End faces (joint surfaces) S2a of the back yokes 22a of the respective adjacent magnetic circuits 30 come into contact with each other. A recess 42 to which the high-magnetic permeability member 40 is fitted is formed in the end face S2a of the back yoke 22a. Adjacent magnetic circuits 30 are connected to each other in a state in which the high-magnetic permeability member 40 is fitted to the respective recesses 42. The back yoke 22b also has the same structure.

The material of the high-magnetic permeability member 40 is not particularly limited, and a material of which the magnetic permeability is higher than that of the yoke 22 may be selected according to the material of the yoke 22. For example, an iron material (SS400) or low-carbon steel having a relative permeability μ/μ₀ of about 1000 is used for the yoke 22. In this case, a material of which the relative permeability (magnetic permeability) is higher than that of the iron material (SS400) or the low-carbon steel, such as pure iron having higher purity, a permalloy (μ/μ₀=8000, μ=1.0×10⁻²H/m), or an iron-cobalt alloy, may be selected for the high-magnetic permeability member 40. In a case in which a permalloy is used for the yoke 22, a material of which the magnetic permeability is higher than that of the permalloy, such as an iron-cobalt alloy or pure iron having high purity, can be used for the high-magnetic permeability member 40.

The structure of the stator 20 according to a first embodiment has been described above. Subsequently, the advantage of the stator 20 will be described.

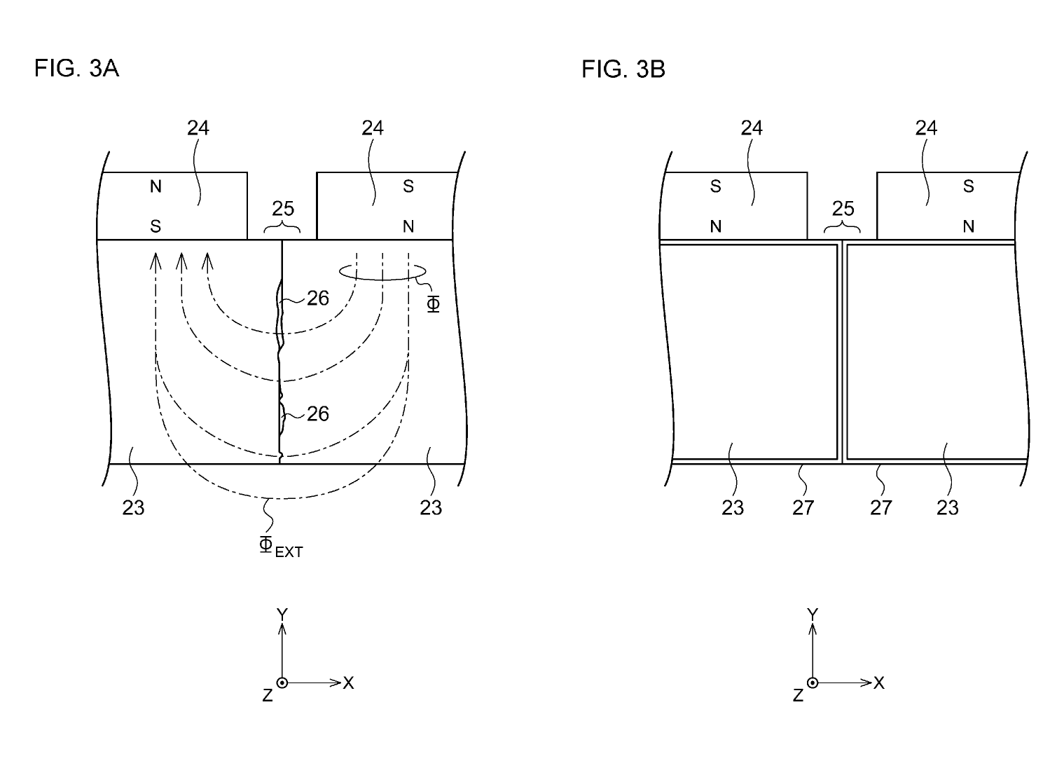

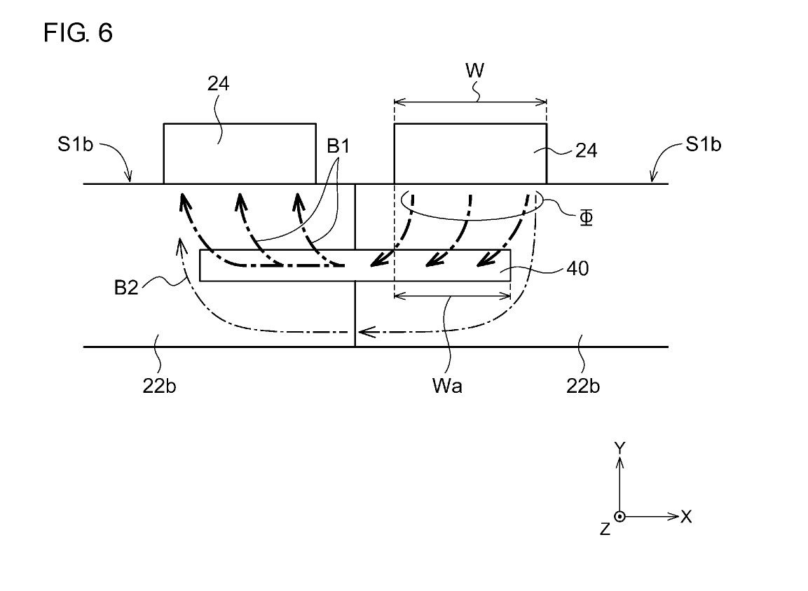

FIG. 6 is a plan view of the stator 20. Magnetic flux Φ is shown in FIG. 6 by a dashed-dotted line. Since the magnetic permeability of the high-magnetic permeability member 40 is higher than that of the yoke 22, the magnetic flux density B1 of magnetic flux passing through the high-magnetic permeability member 40 is higher than the magnetic flux density B2 of magnetic flux passing through the yoke 22. In other words, magnetic flux Φ, which is generated by the field magnets 24, is concentrated on the high-magnetic permeability member 40. Accordingly, magnetic flux Φ, which leaks out of yoke 23, can be reduced in the structure in the related art shown in FIG. 3.

The advantage and effect of the stator 20 according to a first embodiment has been described above.

In order to improve the advantage and effect, it is important to effectively guide the magnetic flux Φ, which is generated by the field magnets 24, to the inside of the high-magnetic permeability member 40. Accordingly, it is preferable that both ends of the high-magnetic permeability member 40 overlap at least a part of the field magnets 24 of the magnetic circuit 30. The high-magnetic permeability member 40 overlaps the field magnets by preferably ¼ or more and more preferably ½ or more of the width W of the field magnet 24 in the movable direction (the x-axis direction). That is, when the overlap width is denoted by W_{OL}, it is preferable that W_{OL}≧W/2 is satisfied.

Further, it is preferable that the high-magnetic permeability member 40 also overlaps at least apart of the field magnets 24 in a height direction (Z direction). In this embodiment, the height h of the high-magnetic permeability member 40 is larger than the height H of the field magnet 24. Accordingly, all the magnetic flux generated from the back of the field magnet 24 (the surface of the field magnet 24 coming into contact with the yoke 22) passes through the high-magneticpermeabilitymember 40 in the height direction.

It is possible to suitably reduce stray magnetic fields by setting the size of the high-magnetic permeability member 40 and the arrangement relationship between the high-magnetic permeability member 40 and the field magnets 24 as described above.

### First Modification

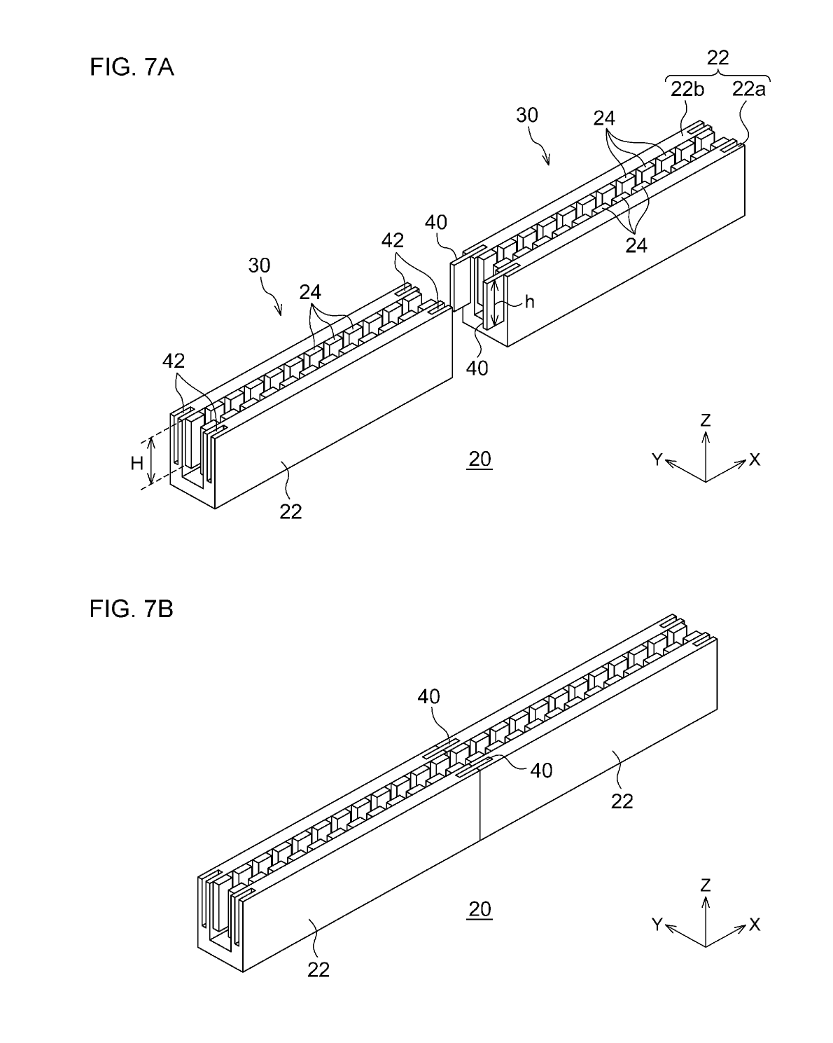

Subsequently, a modification relating to the first embodiment will be described. FIGS. 7A and 7B are perspective views of a stator 20 according to a first modification. In this modification, the height h of a high-magneticpermeabilitymember 40 is substantially equal to the height H of a field magnet 24. The same effect as the first embodiment can be obtained with this modification as well.

### Second Modification

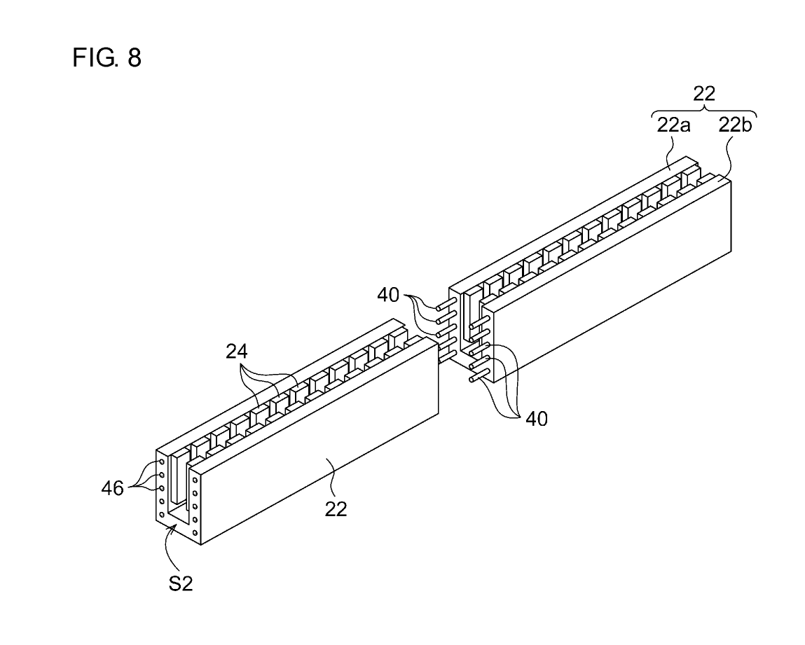

FIG. 8 is a perspective view of a stator 20 according to a second modification. In this modification, high-magnetic permeability members 40 have the shape of a rod. A plurality of holes (recesses) 46 are formed in an end face S2 of each of back yokes 22a and 22b. High-magnetic permeability members 40 are inserted into corresponding holes 46. The same effect as the first embodiment can be obtained with this modification as well.

### Other Modifications

In addition, the shape of the high-magnetic permeability member 40 may be an arbitrary shape without being limited to the shape of a plate and the shape of a rod. Further, the number of high-magnetic permeability members 40, which are provided at the connecting portion, is also not particularly limited.

### Second Embodiment

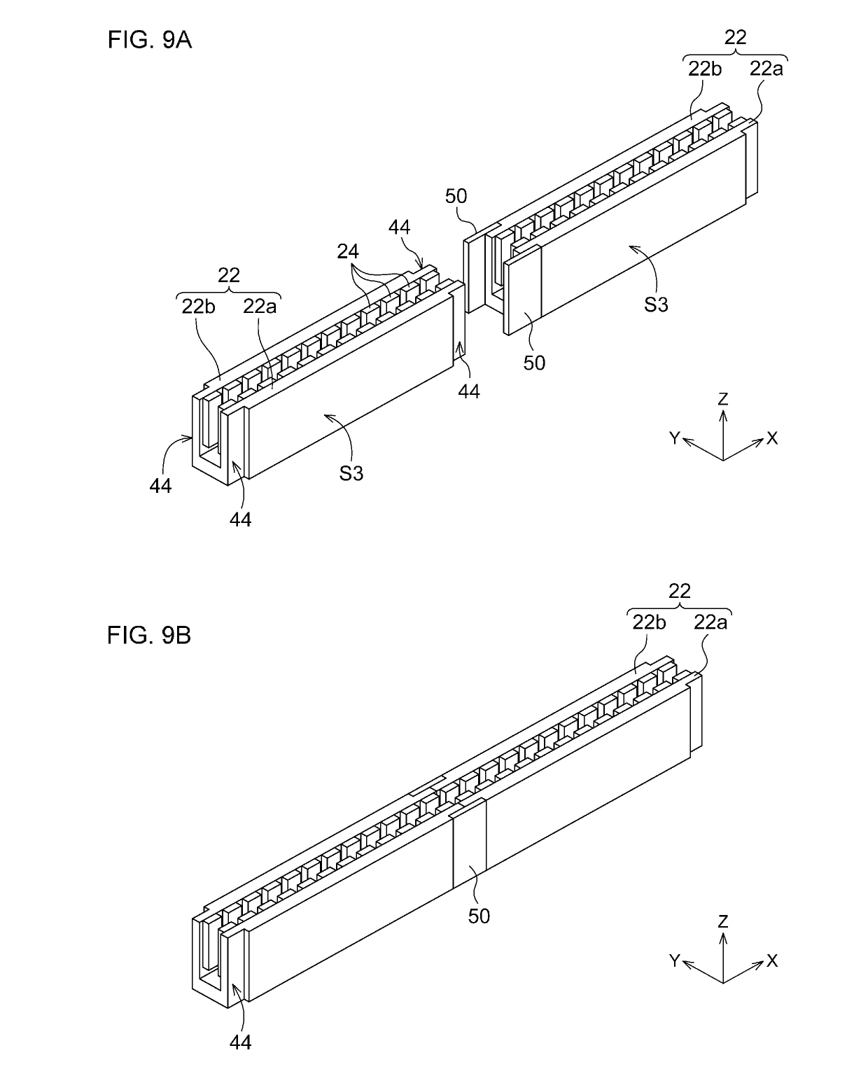

FIGS. 9A and 9B are views of a stator 20 of a linear motor according to a second embodiment. In the second embodiment, the high-magnetic permeability members 40 have been embedded in the yoke 22. However, high-magnetic permeability members 50 are attached to the surface of a yoke 22 in the second embodiment.

Specifically, the high-magnetic permeability members 50 are provided on outer surfaces S3 of the respective back yokes 22a and 22b. A groove 44 is provided at an end portion of the outer surface S3 of each of the back yokes 22a and 22b. The high-magnetic permeability members 50 are embedded in the grooves 44. It is preferable that the surface of the high-magnetic permeability member 50 is flush with the surface of the back yoke 22a (22b) without a step as shown in FIG. 9B. It is possible to reduce a stray magnetic field, which is generated from a step, that is, a discontinuous portion by removing the step between the high-magnetic permeability member 50 and the back yoke 22a (22b).

According to the second embodiment, the high-magnetic permeability members 50 having high magnetic permeability are provided on the surfaces of the yoke 22 at the connecting portion between the magnetic circuits 30. Accordingly, magnetic flux density inside the high-magnetic permeability member 50 is increased and magnetic flux density outside the yoke 22 is relatively reduced. That is, since magnetic flux, which is to leak out of the surface of the yoke 22, can be made to enter the high-magnetic permeability member 50, stray magnetic fields can be reduced.

Further, the second embodiment has an advantage of easily assembling the stator 20 in comparison with the first embodiment.

### Third and Fourth Modifications

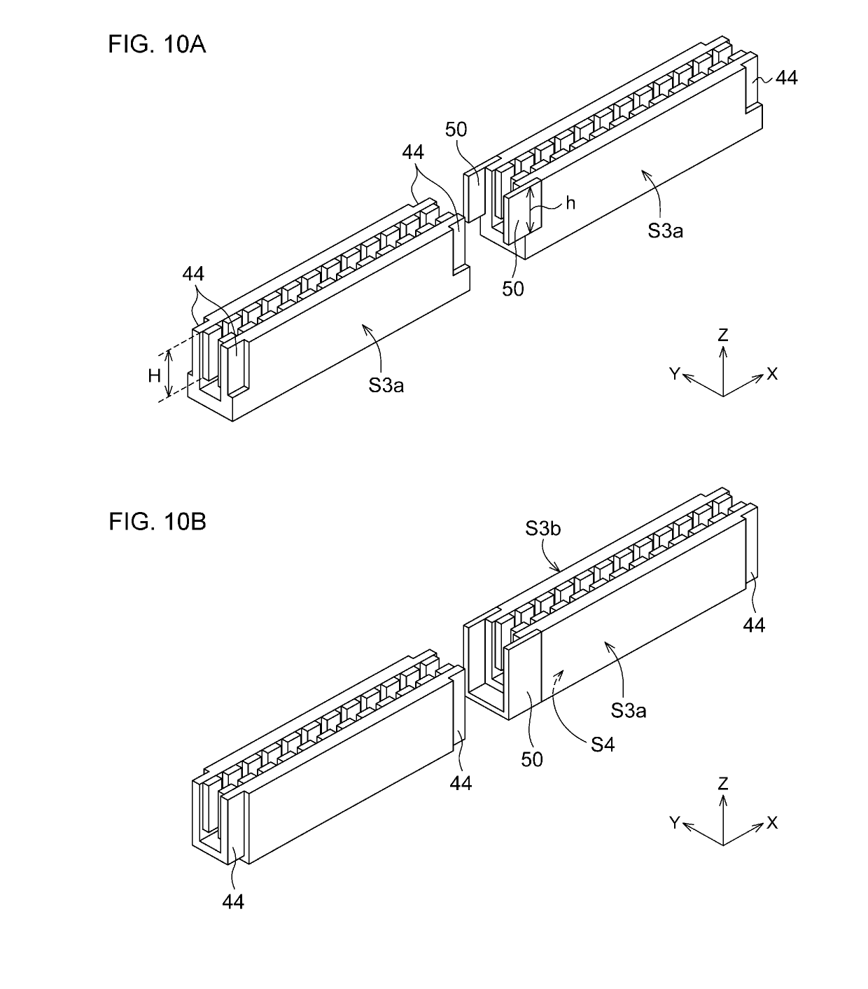

Subsequently, modifications relating to the second embodiment will be described. FIGS. 10A and 10B are perspective views of stators 20 according to third and fourth modifications. In the third modification of FIG. 10A, the height h of a high-magnetic permeability member 50 is substantially equal to the height H of a field magnet 24. The same effect as the first embodiment can be obtained with this modification as well.

In the fourth modification of FIG. 10B, a high-magnetic permeability member 50 having a U shape is provided at a connecting portion between adjacent magnetic circuits 30 so as to cover outer surfaces S3a and S3b of back yokes 22a and 22b and a bottom S4 of a yoke 22. According to this modification, since it is sufficient for one high-magnetic permeability member 50 to be used at one connecting portion, assembling is easier. Further, stray magnetic fields, which are generated from the bottom of the yoke 22, can also be reduced.

### Fifth Modification

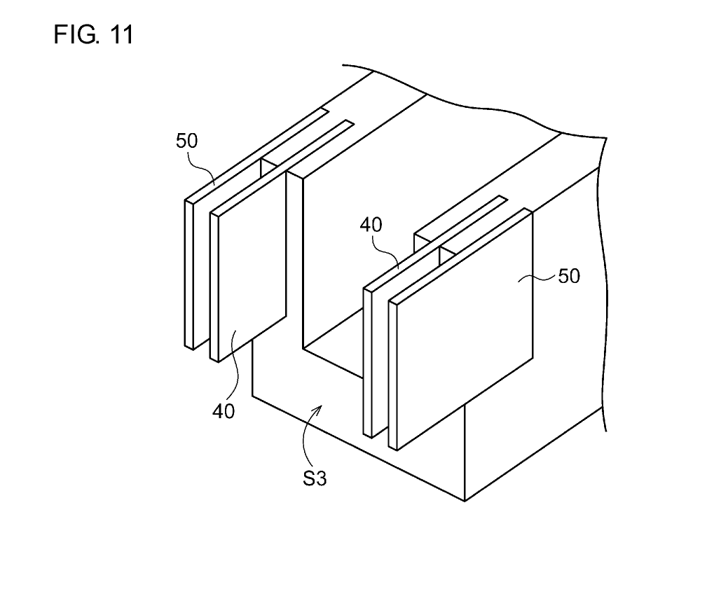

FIG. 11 is a perspective view of a stator 20 according to a fifth modification. The stator 20 includes first high-magnetic permeability members 40 and second high-magnetic permeability members 50. The first high-magnetic permeability members 40 are embedded in a yoke 22 as described in the first embodiment. The second high-magnetic permeability members 50 are provided on the surfaces of the yoke 22 as described in the second embodiment. Since the high-magnetic permeability members 40 and 50 are used together with each other, stray magnetic fields can be further reduced.

### Sixth Modification

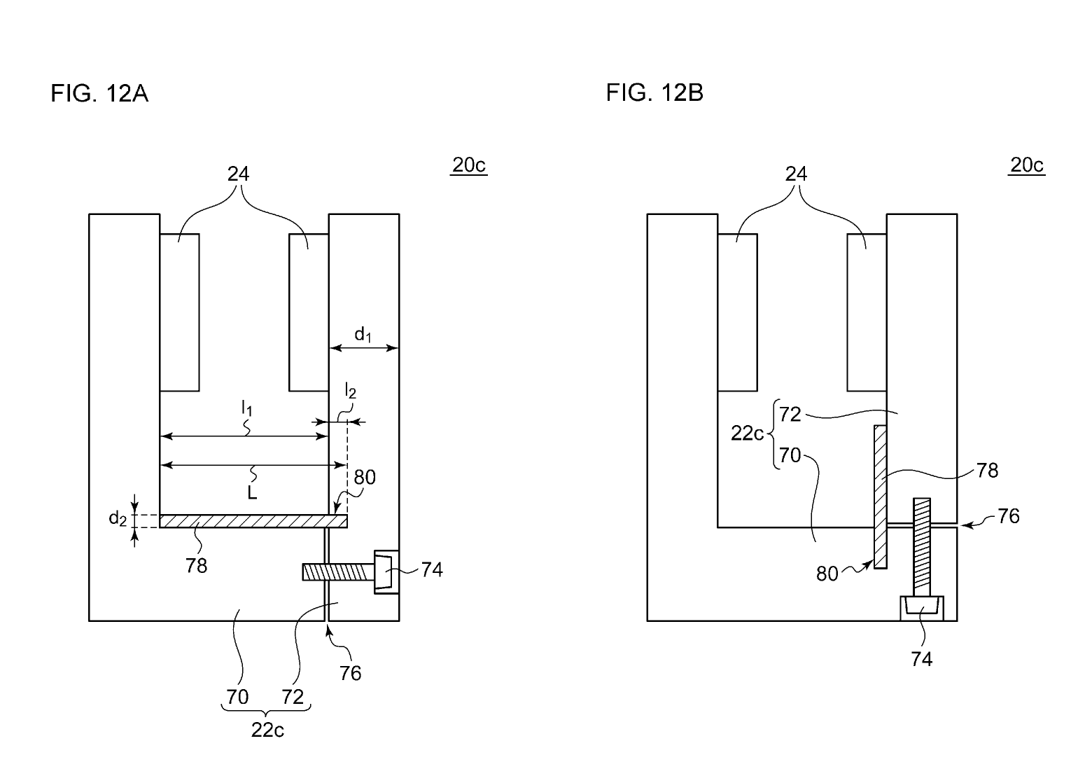

FIGS. 12A and 12B are cross-sectional views of a stator 20c according to a sixth modification. In the above-mentioned embodiments or modifications, the U-shaped yoke 22 of one magnetic circuit 30 has been formed of one component. However, in the sixth modification, a yoke 22c includes a plurality of parts 70 and 72 that are connected to each other. Mechanical coupling means, such as screws 74, may be used for the connection of the parts 70 and 72, or an adhesive may be used for the connection of the parts 70 and 72.

For example, one 70 of the plurality of parts may have an L-shaped cross-sectional shape, and the other 72 may have an I-shaped cross-sectional shape. A high-magnetic permeability member 78 of which the magnetic permeability is higher than that of the yoke 22c is provided on joint surfaces 76 of the plurality of parts 70 and 72 so as to extend across the joint surfaces 76 in a direction orthogonal to the joint surfaces 76. The high-magnetic permeability member 78 may have the shape of a plate.

In the modification of FIG. 12A, the high-magnetic permeability member 78 is attached to the bottom of the U-shaped yoke 22c. The length L of the high-magnetic permeability member 78 is longer than the length 11 of the bottom. A recess 80 to which the high-magnetic permeability member 78 is fitted is formed in the I-shaped part 72. The parts 70 and 72 are connected to each other in a state in which the high-magnetic permeability member 78 is fitted to the recess 80. The length 12 of the recess 80 may be determined so that l₁+l₂≅L is satisfied. The length 12 may be determined in consideration of the thickness d₁ and strength of the I-shaped part 72, the thickness d₂ and strength of the high-magnetic permeability member 78, and the like.

According to this modification, since it is possible to reduce leakage flux at the connecting portion even though the U-shaped yoke 22c is designed so as to be divided into a plurality of parts, it is possible to achieve performance that is not inferior to the performance of the integrated U-shaped yoke 22.

In FIG. 12B, the division form of the L-shaped part 70 and the I-shaped part 72 is different from that of FIG. 12A and others are the same as those of FIG. 12A.

The U-shaped yoke 22c has been divided into two parts 70 and 72 in this modification, but the shapes of the parts are not particularly limited. For example, the U-shaped yoke 22c may be divided into two L-shaped parts at the middle of the bottom thereof. Alternatively, the U-shaped yoke 22c may be divided into three or more parts.

Further, the high-magnetic permeability member 78 has been attached to the bottom of the part 70 of the yoke 22c in the sixth modification. However, the invention is not limited thereto, and a groove 44 may be formed as shown in FIG. 9 or 10 and the high-magnetic permeability member 78 may be embedded in the groove 44.

Furthermore, the shape of the high-magnetic permeability member 78 may be an arbitrary shape without being limited to the shape of a plate and the shape of a rod. Moreover, the number of high-magnetic permeability members 78, which are provided at each joint surface 76, is also not particularly limited.

In the first embodiment or second embodiment and the first to fifth modifications, it is possible to grasp that one long yoke is divided into a plurality of parts for the respective magnetic circuits in the movable direction of the movable element. Accordingly, the following technical idea is derived from the entire specification.

Certain aspects of the invention relate to a linear motor that includes a movable element and a stator. A yoke may be divided into a plurality of parts. The yoke may be provided with a high-magnetic permeability member which is provided so as to extend across joint surfaces of the plurality of parts in a direction orthogonal to the joint surfaces and of which the magnetic permeability is higher than the magnetic permeability of the plurality of parts of the yoke.

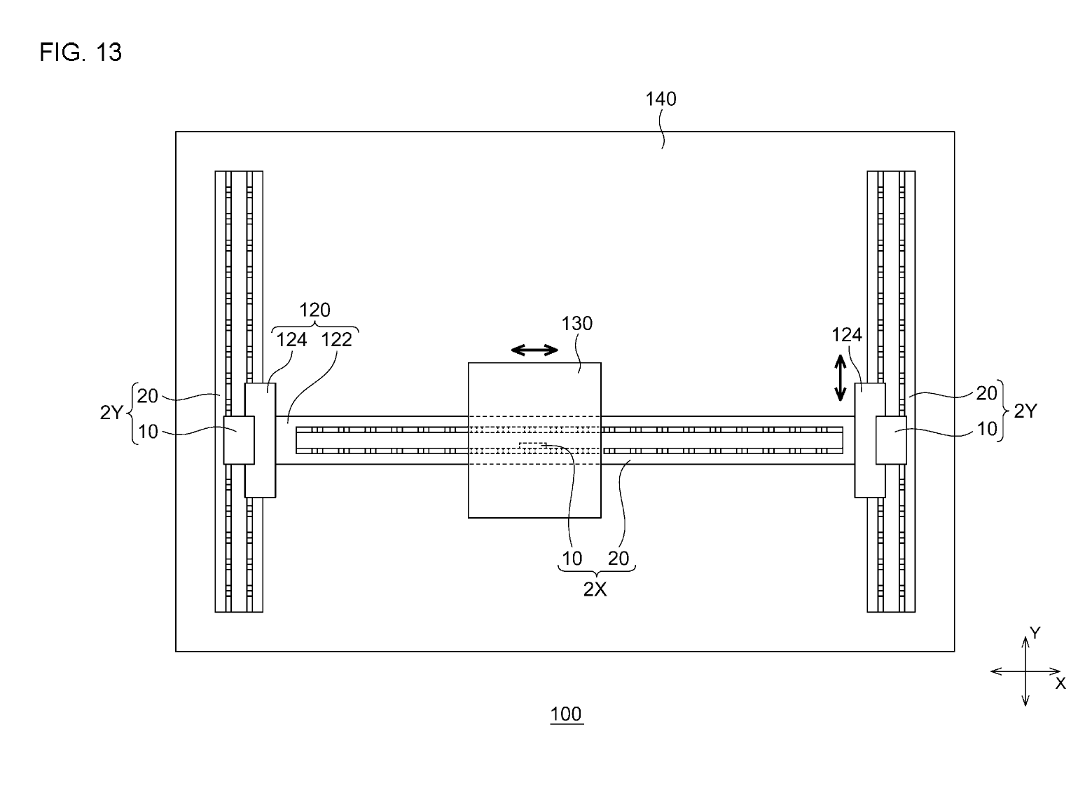

Finally, the use of a linear motor 2 will be described. FIG. 13 is a plan view of a stage device 100 using the linear motor 2 according to the first embodiment. The stage device 100 is called an XY stage, and positions an object in the X direction and the Y direction.

The stage device 100 mainly includes a Y stage 120, an X stage 130, and a surface plate 140. The Y stage 120 includes a pair of sliders 124 and a horizontal member 122 that is horizontally provided between the pair of sliders 124. An X linear motor 2X, which moves the X stage 130 in the X direction, is provided on the horizontal member 122. The X linear motor 2X includes a stator 20 that is fixed to the horizontal member 122 and extends in the X direction, and a movable element (coil) 10 that is joined to the lower surface of the X stage 130. Accordingly, the X stage 130 is positioned in the X direction by the control of the movable element 10 of the X linear motor 2X.

A pair of Y linear motors 2Y are provided on both ends of the surface plate 140. Each of the Y linear motors 2Y includes a movable element 10 and a stator 20. The above-mentioned sliders 124 are fixed to the stators 20 of the Y linear motors 2Y. The Y stage 120 is positioned in the Y direction by the control of the movable elements 10 of the Y linear motors 2Y.

The structure of the stage device 100 has been described above. The linear motor 2 according to the first embodiment can be suitably used for the X linear motor 2X or the Y linear motor 2Y of the stage device 100. The stage device 100 can be used to position a wafer or a glass substrate of an exposure device, or can also be used for an actuator or the like used for a scanning electron microscope (SEM).

While the preferred embodiments of the present invention have been described using specific terms, such description is for illustrative purposes only, and it is to be understood that changes and variations may be made without departing from the spirit or scope of the appended claims.

1: A linear motor comprising:
a movable element; and
a stator composed of a plurality of magnetic circuits connected along the movable element's axis of movement; wherein
the magnetic circuits are furnished with yokes and pluralities of field magnets fixed to the yokes, and
high-magnetic permeability members of magnetic permeability higher than that of the yokes are provided where adjoining magnetic circuits are connected, such as to straddle the connections.

2: The linear motor according to claim 1, wherein high-magnetic permeability members, at either of ends thereof, overlap at least a portion of the magnetic-circuit field magnets.

3: The linear motor according to claim 1, wherein the high-magnetic permeability members are embedded in the yokes.

4: The linear motor according to claim 1, wherein the high-magnetic permeability members are provided superficially on the yokes.

5: The linear motor according to claim 1, wherein:
the yokes include pairs of yoke backs provided facing each other such as to sandwich the movable element along a way perpendicular to its axis of movement;
the plurality of field magnets are provided on inner-side lateral faces of the yoke backs; and
recesses into which the high-magnetic permeability members are fitted are formed in end-portion lateral faces of the yoke backs.

6: The linear motor according to claim 1, wherein:
the yokes include pairs of yoke backs provided facing each other such as to sandwich the movable element along a way perpendicular to its axis of movement;
the plurality of field magnets are provided on inner-side lateral faces of the yoke backs; and
the high-magnetic permeability members are provided on outer-side lateral surfaces of the yoke backs.

7: The linear motor according to claim 5, wherein grooves are provided in outer-side lateral surfaces of the yoke backs, and the high-magnetic permeability members are embedded in the grooves.

8: A stage device comprising the linear motor according to any one of claim 1.

9: A linear motor having a movable element and a stator; wherein
the stator comprises a yoke constituted split into a plurality of sections, and high-magnetic permeability members provided straddling, at right angles to, surfaces where the plurality of sections join, and being of magnetic permeability higher than that of the plurality of sections.

10: A stage device comprising the linear motor according to claim 9.
